(19) United States
(12) Patent Application Publication
(10) Pub. No.: US 2025/0388475 A1
(43) Pub. Date: Dec. 25, 2025

(54) SILICON CARBIDE FILLER, COMPOSITE MATERIAL, AND SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Hideyuki UEHIGASHI, Nisshin-shi (JP); Tomohito IWASHIGE, Nisshin-shi (JP); Takahiro KANDA, Nisshin-shi (JP); Hideo MATSUKI, Nisshin-shi (JP); Kazuki KUWATA, Nisshin-shi (JP); Soma SAKAKIBARA, Nisshin-shi (JP)

(21) Appl. No.: 19/204,811

(22) Filed: May 12, 2025

(30) Foreign Application Priority Data
Jun. 19, 2024 (JP) 2024-098408

(51) Int. Cl. C01B 32/956; C08K 3/34; C08K 7/16; C22C 29/06; H01L 23/373

(52) U.S. Cl. CPC C01B 32/956; C08K 3/34; C08K 7/16; C22C 29/065; H01L 23/3733; C01P 2002/76; C01P 2004/02; C01P 2004/03; C01P 2004/52; C01P 2004/61

(57) ABSTRACT

A composite material includes a continuous phase and a silicon carbide filler. The continuous phase is made of a metal or a synthetic resin. The silicon carbide filler is dispersed in the continuous phase and includes dendritic crystals having a circularity in a cross-sectional view of less than 0.206. A semiconductor device includes a semiconductor element and a bonded member formed from the composite material into a plate shape or a layer shape and bonded to the semiconductor element.

### CROSS REFERENCE TO RELATED APPLICATION

The present application claims the benefit of priority from Japanese Patent Application No. 2024-098408 filed on Jun. 19, 2024. The entire disclosure of the above application is incorporated herein by reference.

### TECHNICAL FIELD

The present disclosure relates to a silicon carbide (SiC) filler, a composite material containing the SiC filler, and a semiconductor device including the composite material.

### BACKGROUND

Composite materials metals and nonmetallic inorganic materials are often used as heat dissipation members for semiconductor elements. JP 2011-080145 A (corresponding to US 2011/0256419 A1 and US 2015/0225635 A1) discloses a composite member of magnesium or a magnesium alloy and SiC. The composite member contains, for example, more than 70 volume % SiC, has a thermal expansion coefficient of 4 ppm/K or more and 8 ppm/K or less, and has a thermal conductivity of 180 W/m. K or more. Since the composite member has an excellent thermal expansion coefficient matching with semiconductor elements and also has excellent heat dissipation properties, the composite member can be suitably used as a heat dissipation member for semiconductor elements.

### SUMMARY

The present disclosure provides an SiC filler, a composite material, and a semiconductor device. The silicon carbide filler may include dendric crystals having a circularity in a cross-sectional view of less than 0.206. The composite material may include a continuous phase made of a metal or a synthetic resin, and the SiC filler dispersed in the continuous phase. The semiconductor device may include a semiconductor element, and a bonded member formed from the composite material into a plate shape or a layer shape and bonded to the semiconductor element.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view illustrating a schematic configuration example of a composite material including an SiC filler according to the present embodiment;

FIG. 2 is an enlarged optical microscope photograph of the SiC filler illustrated in FIG. 1;

FIG. 3 is a graph showing the particle size distribution of the SiC filler shown in FIG. 2 after dry classification;

FIG. 4 is a table showing the evaluation results of the specific surface area of the SiC filler shown in FIG. 2 after dry classification;

FIG. 5 is a photograph showing scanning electron microscope images of cross sections of a synthetic resin in which the SiC filler according to the present embodiment is dispersed, and binarized images of one particle of the SiC filler in the respective scanning electron microscope images;

FIG. 6 is a photograph showing scanning electron microscope images of cross sections of a synthetic resin in which a commercially available filler is dispersed, and binarized images of one particle of the commercially available filler in the respective scanning electron microscope images;

FIG. 7 is a table showing the evaluation results of the circularities of the fillers shown in FIG. 5 and FIG. 6;

FIG. 8 is a cross-sectional view illustrating another configuration example of a composite material including the SiC filler according to the present embodiment;

FIG. 9 is a cross-sectional view illustrating a configuration example of a semiconductor device using the composite material according to the embodiment;

FIG. 10 is a cross-sectional view illustrating another configuration example of a semiconductor device using the composite material according to the present embodiment;

FIG. 11 is a cross-sectional view illustrating yet another configuration example of a semiconductor device using the composite material according to the present embodiment; and

FIG. 12 is a cross-sectional view illustrating yet another configuration example of a semiconductor device using the composite material according to the present embodiment.

### DETAILED DESCRIPTION

In recent years, SiC has begun to be widely used as a power semiconductor material capable of reducing power loss. Compared to other existing materials such as silicon (Si), SiC has higher thermal conductivity and dielectric breakdown field strength, enabling high-temperature operation. Consequently, as SiC is increasingly replacing Si, SiC device packages are being used in more demanding environments. In particular, durability against temperature cycling is required. Additionally, the packaging materials in contact with SiC semiconductor elements require a small difference in the coefficient of thermal expansion and high thermal conductivity.

According to one aspect of the present disclosure, an SiC filler includes dendric crystals having a circularity in a cross-sectional view of less than 0.206. According to another aspect of the present disclosure, a composite material includes a continuous phase made of a metal or a synthetic resin, and the SiC filler dispersed in the continuous phase. According to another aspect of the present disclosure, a semiconductor device includes a semiconductor element, and a bonded member formed from the composite material into a plate shape or a layer shape and bonded to the semiconductor element.

### Embodiment

Hereinafter, an embodiment of the present disclosure will be described with reference to the accompanying drawings. It should be noted that the following embodiment, its variations, and the accompanying drawings are simplified or schematic representations provided to concisely explain the content of the present disclosure and do not limit the scope of the present disclosure in any way. Therefore, it is understood that the descriptions in the drawings may not necessarily correspond exactly to the specific device configurations that are actually manufactured and sold. In other words, unless explicitly limited by the applicants during the prosecution of the present application, the present disclosure should not be construed as being limited by the descriptions in the drawings or the configurations, functions, or operations described hereinafter.

### SiC Filler and Composite Material Including the Same

As described above, the packaging materials in contact with SiC semiconductor elements require a small difference in the coefficient of thermal expansion and high thermal conductivity. In this regard, JP 2011-080145 A proposes the composite member composed of magnesium or a magnesium alloy and SiC, which has the following features (i) or (ii), thereby achieving a composite material with a low coefficient of thermal expansion and high thermal conductivity.
(i) The composite member contains more than 70 volume % SiC.
(ii) The composite member contains 50 volume % or more of SiC and has a network portion that bonds SiC particles together.

Here, basically, as the content of a filler made of SiC increases, the coefficient of thermal expansion decreases, and the thermal conductivity improves. However, many such composite materials achieve only about half of the inherent thermal conductivity of SiC, which is 490 W/mK. Even in JP 2011-080145 A, the highest thermal conductivity value is 318 W/mK, which is achieved when the composite contains 85.7 volume % of SiC and the network portion is relatively thick.

In this regard, when the filler has an irregular shape, as represented by the aspect ratio, it is expected that the thermal conductivity will improve due to increased contact between particles of the filler. Therefore, there is a need for fillers with irregular particle shapes that can further enhance thermal conductivity.

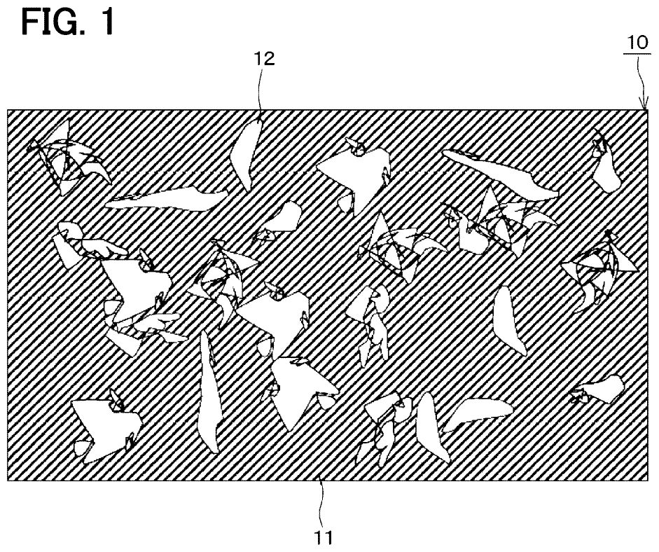

Therefore, the present embodiment aims to achieve further improvement in thermal conductivity while maintaining a low coefficient of thermal expansion. Specifically, referring to FIG. 1, the composite material 10 according to the present embodiment has a structure in which an SiC filler 12 is dispersed within a continuous phase 11 made of metal or synthetic resin. Hereinafter, the continuous phase 11 may be referred to as a “main phase”. The SiC filler 12 includes powder particles made of dendric crystals having a circularity in a cross-sectional view of less than 0.206. The powder particles have a particle size in a range from 10 to 100 micrometers. The particle size of the SiC filler 12 means a median diameter. The SiC filler 12 has one or more crystal polytypes selected from the group consisting of 3C, 4H, 6H, and 15R. An average circularity of the SiC filler 12 is 0.20 or less.

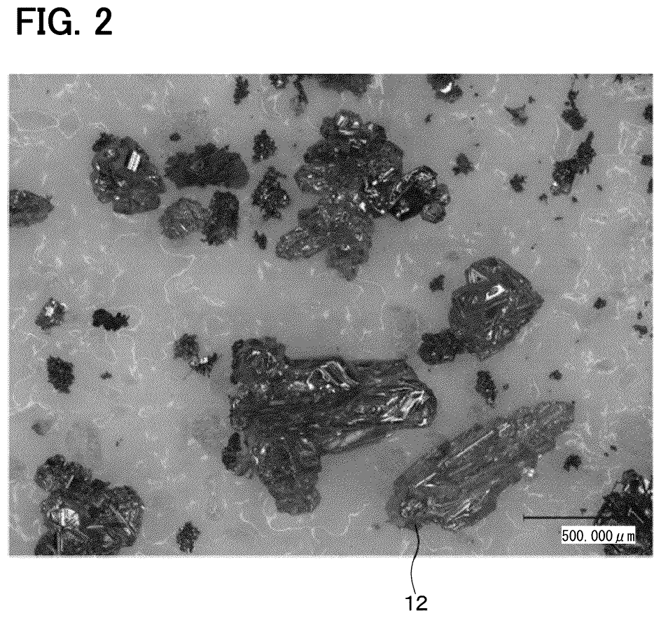

As a result of diligent research by the inventors, it was found that SiC undergoes dendritic crystal growth when chemical vapor deposition (CVD) growth of SiC is performed in a system with a small thermal gradient in a crystal growth portion. FIG. 2 shows an optical microscope photograph of a particle group of the SiC filler 12 obtained through dendritic crystal growth. The method for dendritic crystal growth is as follows, for example. Using a source gas containing Si and C along with a carrier gas, a source gas decomposition zone is controlled to a temperature of 1500 to 3000° C., a dendritic crystal deposition zone is controlled to a temperature of 2500° C. or less, and a temperature gradient in the dendritic crystal deposition zone in a growth axis direction is controlled to 5° C./mm or less. The source gas is SiH₄, trichlorosilane, or C₃H₈. The carrier gas is H₂ or Ar. The dendritic crystal deposition zone may be a graphite member.

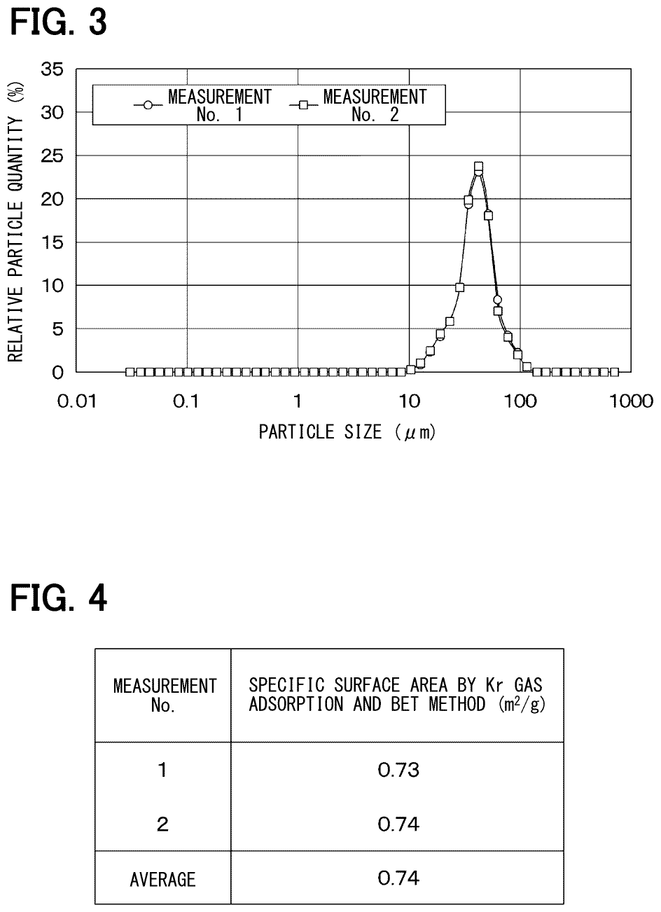

The obtained dendritic particles were classified, and their surface area, which is one of the indices relating to a degree of shape distortion, was evaluated. The results are shown in FIG. 3 and FIG. 4. From the results shown in FIG. 3, a frequency median (that is, median) diameter of the particles classified this time was 36.3 μm. The specific surface area of a simple SiC sphere with a diameter of 36.3 μm is 0.05 m²/g.

Herein, the surface area ratio is defined as follows:

$$( Surface Area Ratio ) = ( Specific Surface Area of Classified Particles ) / ( Specific Surface Area of a Simple Sphere with the Median Diameter of Classified Particles )$$

In this case, the value of the numerator is 0.74 m²/g as shown in FIG. 4, and the value of the denominator is 0.05 m²/g as described above. Therefore, the surface area ratio is 14.3. That is, in the SiC filler 12 according to the present embodiment, the surface area is 14.3 times greater than that of the simple sphere, indicating that the particles have highly irregular shapes.

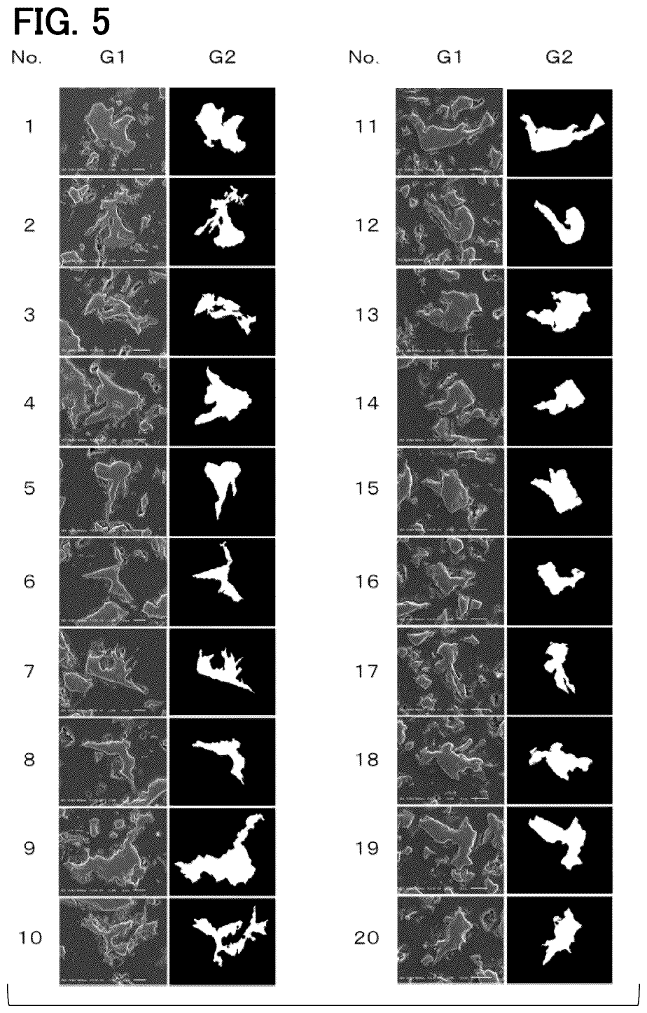

The results of evaluation of the circularity in a cross-sectional view of the SiC filler 12 according to the present embodiment will be described with reference to FIGS. 5 to 7. The circularity is expressed by the following formula. The circularity is an index that equals 1 for a perfect circle, and the smaller the value, the more deformed the shape is.

$$( Circularity ) = 4 π \cdot ( Area ) / {( Perimeter )}^{2}$$

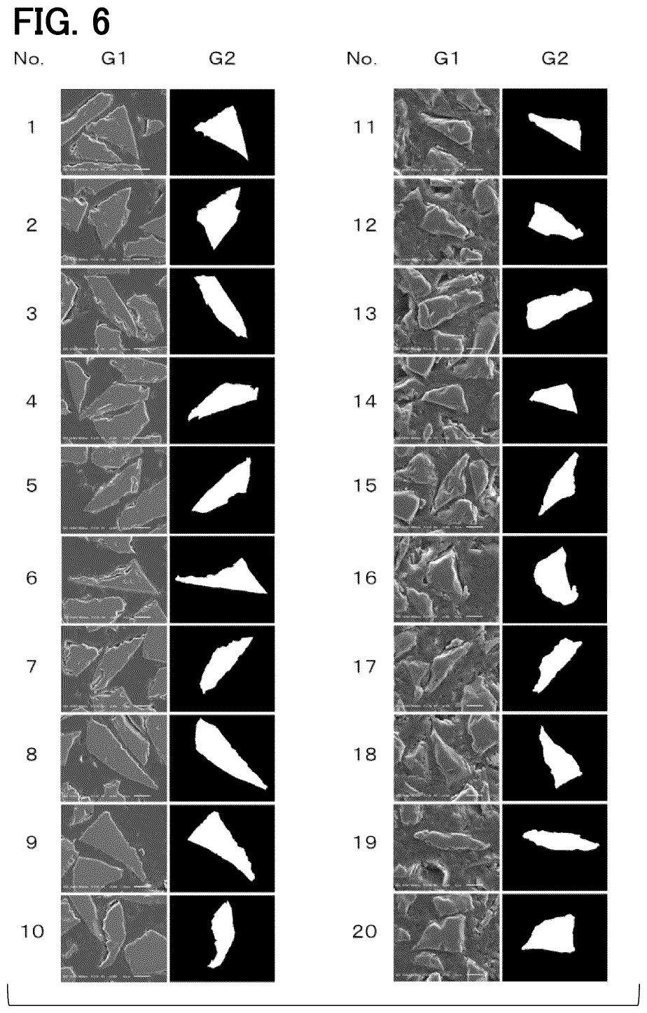

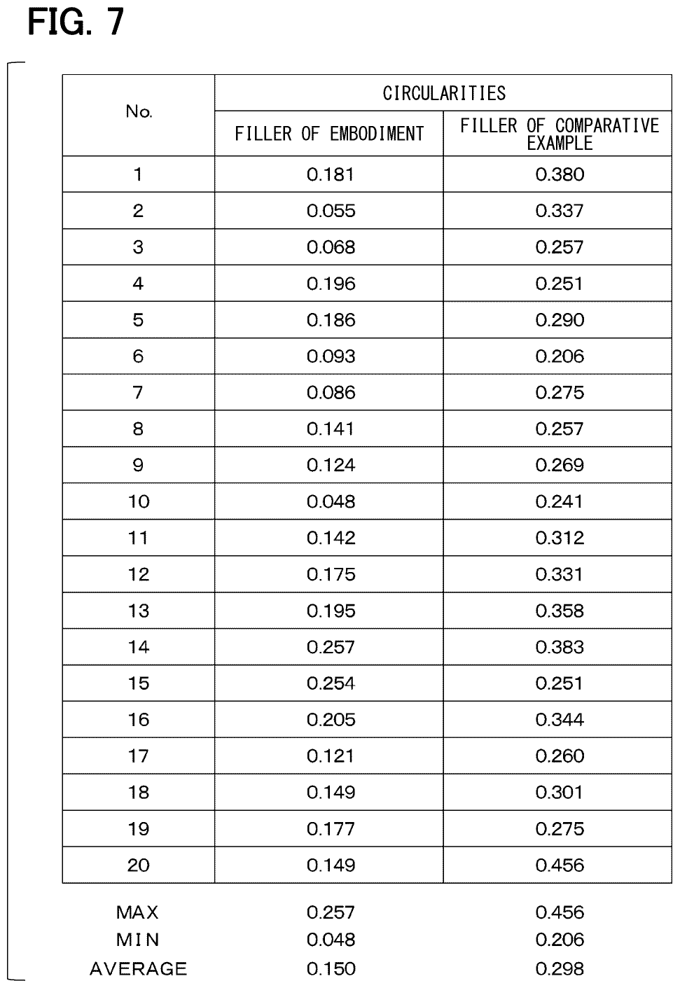

In FIG. 5, G1 shows scanning electron microscope (SEM) images of a cross section where the SiC filler 12 according to the present embodiment is dispersed in a synthetic resin. Twenty particles with relatively distinct shapes were selected as focus particles and are labeled as No. 1 to No. 20. In FIG. 5, G2 shows binarized images of respective focus particles from No. 1 to No. 20. FIG. 6 shows a similar depiction for commercially available crushed filler as a comparative example. FIG. 7 is a table showing the calculated circularities for the respective focus particles from No. 1 to No. 20 shown in FIG. 5 and FIG. 6, along with the maximum, minimum, and average circularities.

The circularity of the SiC filler 12 according to the present embodiment had smaller values compared to the commercially available crushed filler. This indicates that the particles were more deformed and had larger surface areas. While the minimum circularity of the commercially available crushed filler was 0.206, the average circularity of the SiC filler 12 according to the present embodiment was lower, at 0.150. In addition, the maximum circularity and the minimum circularity of the SiC filler 12 according to the present embodiment were 0.257 and 0.048, respectively.

Thus, the SiC filler 12 according to the present embodiment is made of dendric crystals having a circularity of less than 0.206. The average circularity of the dendric crystals of the SiC filler 12 may be 0.20 or less. Furthermore, from the viewpoint of reducing the difference in thermal expansion coefficient and improving the thermal conductivity, the average circularity of the dendric crystals of the SiC filler 12 may be 0.15 or less. The average circularity is calculated by selecting 20 particles from the scanning electron microscope images of the cross section whether the SiC filler 12 is dispersed in the synthetic resin as described above, calculating the circularity of each of the 20 particles, and averaging the circularity of the 20 particles. The composite material 10 according to the present embodiment has a structure in which the SiC filler 12 is dispersed in the continuous phase 11 made of a metal or synthetic resin. As a result, when the composite material 10 is used as a packaging material in contact with SiC semiconductor elements, it is possible to reduce the difference in the coefficient of thermal expansion while improving thermal conductivity.

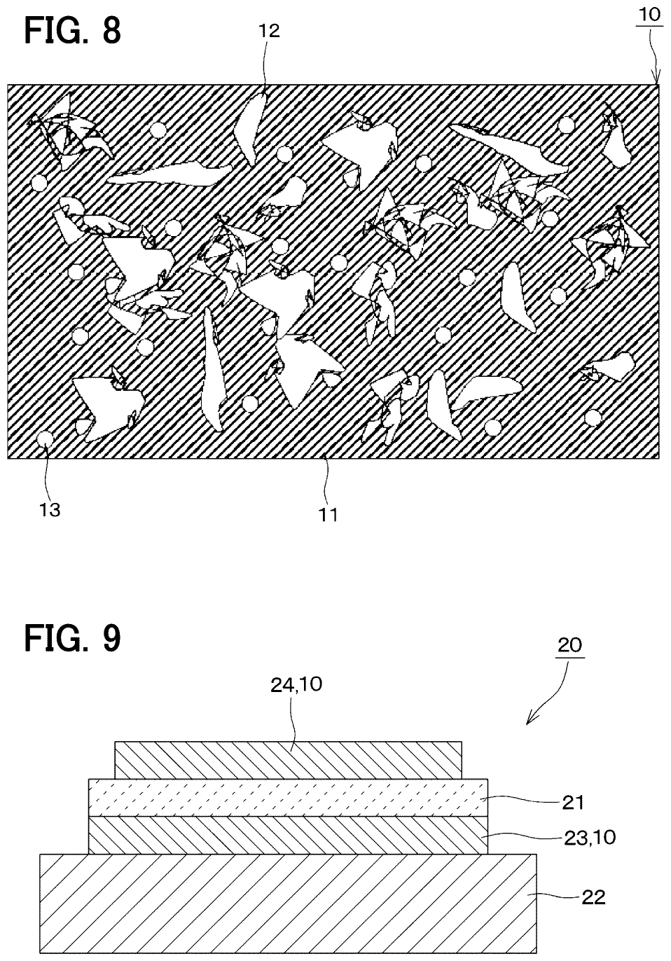

As shown in FIG. 8, the composite material 10 may further include an additional filler 13 different from the SiC filler 12 having the characteristics described above. The additional filler 13 may be a filler made of a material different from SiC. The additional filler 13 may be any one of diamond, aluminum nitride (AlN), Si, and carbon (for example, carbon nanotubes or the like), or a combination of these. This improves the filling rate, thereby making it possible to further improve the thermal conductivity. Here, the shape of the additional filler 13 is not particularly limited, and may be, for example, spherical, polyhedral, or amorphous.

### Semiconductor Device

Configuration examples of a semiconductor device 20 using the composite material 10 including the SiC filler 12 according to the present embodiment will be described below with reference to FIG. 9 and other figures. Note that in FIG. 9 and other figures, the vertical direction in the drawings is for illustration convenience only and does not necessarily correspond to the direction of gravitational force.

First, referring to FIG. 9, the semiconductor device 20 includes a semiconductor element 21, a heat dissipation member 22, a first bonded member 23, and a second bonded member 24. That is, the semiconductor device 20 is configured as an assembly of the semiconductor element 21, the heat dissipation member 22, the first bonded member 23, and the second bonded member 24.

The semiconductor element 21 has a configuration as an SiC semiconductor element. The heat dissipation member 22 is a so-called heat sink for cooling the semiconductor element 21, and is made of a metal having high thermal conductivity, such as aluminum. The first bonded member 23 is disposed between a lower surface of the semiconductor element 21 and an upper surface of the heat dissipation member 22. The first bonded member 23 is the composite material 10 formed in a plate or layer shape with a metal as the main phase, and is bonded to the semiconductor element 21 and the heat dissipation member 22. The second bonded member 24 is the composite material 10 formed in a plate or layer shape with a metal as the main phase, and is bonded to an upper surface of the semiconductor element 21.

In this configuration, the first bonded member 23 formed from the composite material 10 according to the present embodiment can effectively promote heat dissipation from the semiconductor element 21 to the heat dissipation member 22. Moreover, the second bonded member 24 formed from the composite material 10 according to the present embodiment can effectively promote heat dissipation from the semiconductor element 21 to the outside air.

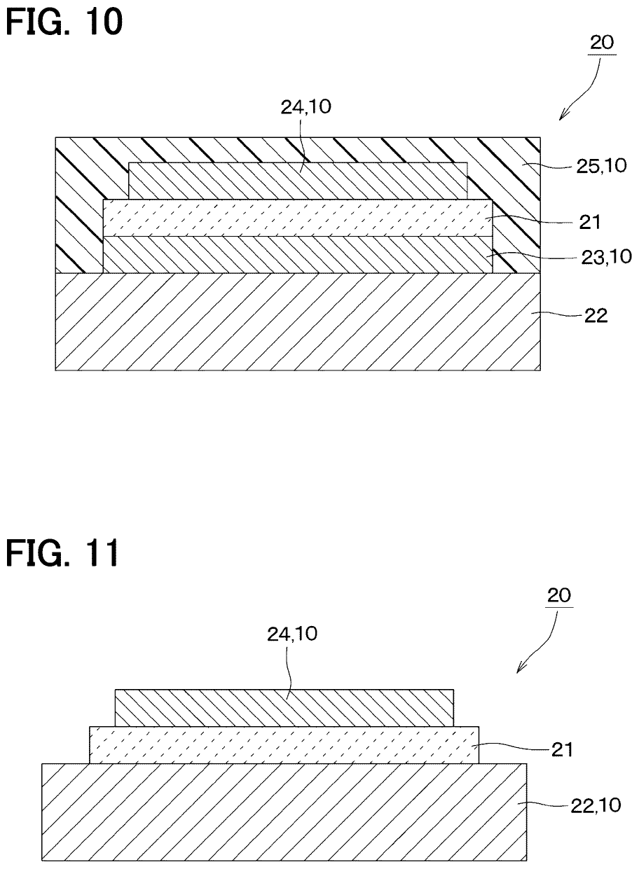

FIG. 10 illustrates a configuration example in which an insulation package 25 that covers the semiconductor element 21, the first bonded member 23, and the second bonded member 24 is added to the configuration example illustrated in FIG. 9. Here, the insulation package 25 can be formed from the composite material 10, with a synthetic resin as the main phase. As a result, the heat dissipation from the semiconductor element 21 to the outside air can be further improved.

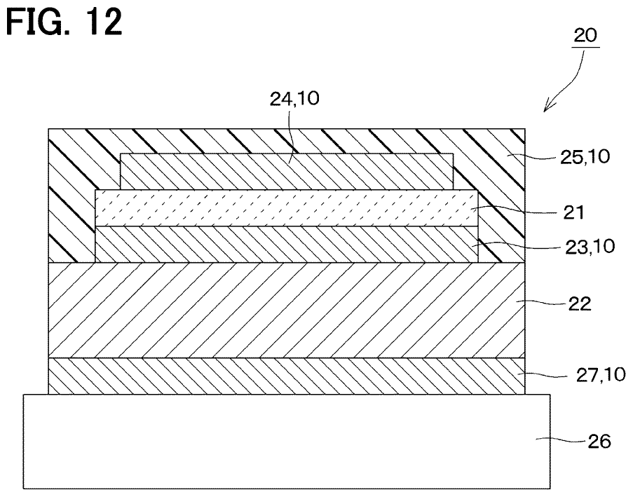

FIG. 11 illustrates a configuration example in which the first bonded member 23 is omitted by forming the heat dissipation member 22 from the composite material 10 including a metal as the main phase in the configuration example illustrated in FIG. 9. With such a configuration, effects similar to those achieved by the configuration example illustrated in FIG. 9 can be obtained.

FIG. 12 illustrates a configuration example in which a cooling device 26 is added to the configuration example illustrated in FIG. 10. The cooling device 26 is joined to the heat dissipation member 22 via a thermal interface material (TIM) 27. The cooling device 26 is configured to dissipate the heat absorbed from the heat dissipation member 22 to the outside by, for example, passing a refrigerant such as cooling water through the inside of the cooling device 26. By forming the TIM 27 using the composite material 10, with metal as the main phase, the cooling efficiency of the heat dissipation member 22 by the cooling device 26 is significantly improved.

### Modifications

The present disclosure is not necessarily limited to the above-described embodiment. It is possible to properly change the above-described embodiment. The following will describe typical modifications. In the following description of modifications, differences from the above-described embodiment will be mainly described. In the following modifications, the same reference symbols as the above-described embodiment are assigned to the same or equivalent parts. Therefore, in the description of the following modifications, regarding components having the same reference symbols as the components of the above-described embodiment, the description in the above-described embodiment can be appropriately incorporated unless there is a technical contradiction or a specific additional description.

The present disclosure is not limited to the specific configurations or structures described in the above-described embodiment and examples. That is, for example, the SiC filler 12 may include SiC powder particles that do not satisfy the above conditions, such as SiC powder particles with a circularity of 0.206 or more. In other words, the SiC filler 12 may include a mixed powder of dendritic crystals with a circularity of 0.206 or more and dendritic crystals with a circularity of less than 0.206, which can be dispersed in the continuous phase 11. The SiC dendritic crystal powder particles having a circularity of 0.206 or more may be regarded as being the additional filler 13 illustrated in FIG. 8.

With reference to FIG. 9 and other figures, either the first bonded member 23 or the second bonded member 24 may be formed from a material different from the composite material 10. The cooling device 26 illustrated in FIG. 12 may be configured without using a refrigerant, for example, may be configured using a Peltier element.

The constituent element(s) of each of the above-described embodiment is/are not necessarily essential unless it is specifically stated that the constituent element(s) is/are essential in the above-described embodiment, or unless the constituent element(s) is/are obviously essential in principle. When numerical values such as the number, amount, and range of elements are mentioned, the present disclosure is not limited to the specific numerical values unless otherwise specified as essential or obviously limited to the specific numerical values in principle. Similarly, in the case where the shape, the direction, the positional relationship, and/or the like of the constituent element(s) is specified, the present disclosure is not necessarily limited to the shape, the direction, the positional relationship, and/or the like unless the shape, the direction, the positional relationship, and/or the like is/are indicated as essential or is/are obviously essential in principle.

The modifications are not limited to the above-described examples. That is, for example, apart from the above-described examples, multiple configuration examples can be combined unless there is a technical contradiction. Similarly, multiple modifications may be combined with each other unless there is a technical contradiction.

What is claimed is:

1. A silicon carbide filler comprising dendric crystals having a circularity in cross-sectional view of less than 0.206.

2. The silicon carbide filler according to claim 1, wherein the dendric crystals have one or more crystal polytypes selected from a group consisting of 3C, 4H, 6H, and 15R.

3. The silicon carbide filler according to claim 1, wherein the dendric crystals have a particle size in a range from 10 to 100 μm.

4. The silicon carbide filler according to claim 1, wherein an average value of the circularity of the dendric crystals is 0.20 or less.

5. A composite material comprising:
a continuous phase made of a metal or a synthetic resin; and
a silicon carbide filler dispersed in the continuous phase and including dendritic crystals having a circularity in a cross-sectional view of less than 0.206.

6. The composite material according to claim 5, further comprising an additional filler different from the silicon carbide filler.

7. The composite material according to claim 6, wherein the additional filler has a spherical shape.

8. A semiconductor device comprising:
a semiconductor element; and
a bonded member formed from a composite material into a plate shape or a layer shape and bonded to the semiconductor element, wherein
the composite material includes:
a continuous phase made of a metal or a synthetic resin; and
a silicon carbide filler dispersed in the continuous phase and including dendritic crystals having a circularity in a cross-sectional view of less than 0.206.
